(19) United States
(12) Patent Application Publication
(10) Pub. No.: US 2026/0205059 A1
(43) Pub. Date: Jul. 16, 2026

(54) POWER AMPLIFIER ARRANGEMENT WITH ENHANCED BANDWIDTH

(71) Applicant: Telefonaktiebolaget LM Ericsson (publ), Stockholm (SE)

(72) Inventors: Mingquan Bao, Västra Frölunda (SE); David Gustafsson, Sävedalen (SE); Kristoffer Andersson, Göteborg (SE)

(21) Appl. No.: 19/232,760

(22) Filed: Jun. 9, 2025

Related U.S. Application Data
(63) Continuation of application No. PCT/SE2022/051160, filed on Dec. 8, 2022.

(51) Int. Cl. H03F 1/02; H03F 1/56; H03F 3/24; H03F 3/60

(52) U.S. Cl. CPC H03F 1/0288; H03F 1/56; H03F 3/245; H03F 3/602; H03F 2200/192

(57) ABSTRACT

A power amplifier arrangement is disclosed which is a Doherty power amplifier based on two coupled transmission lines. The arrangement comprises a first power amplifier which is a main amplifier, and a second a power amplifier which is an auxiliary amplifier. The arrangement further comprises an input power splitter and a quadrature coupler comprising two coupled transmission lines. The isolation port of the quadrature coupler is open. A coupling coefficient of the two coupled transmission lines is determined based on an output power backoff level at which the arrangement is desired to operate. The characteristic impedance of the two coupled transmission lines is determined by an optimal load impedance of the first power amplifier and the coupling coefficient of the two coupled transmission lines. The impedance of the quadrature coupler is determined by the optimal impedance of the first power amplifier and transition point ξ_{b} of the voltage drive level.

### RELATED APPLICATIONS

The present application is a continuation of International Application Number PCT/SE2022/051160 filed Dec. 8, 2022, the disclosure of which is incorporated herein by reference in its entirety.

### TECHNICAL FIELD

Embodiments herein relate to power amplifier arrangement. In particular, they relate to power amplifier arrangement with enhanced bandwidth. Further, the embodiments relate to an electronic device comprising the power amplifier arrangement.

### BACKGROUND

In a wireless communication system, a transmitter employs power amplifiers (PA) to increase radio frequency (RF) signal power before transmission. A PA is expected to amplify input signals linearly and generate output signals with larger power but with identical characteristics to the input signals.

New frequency bands are assigned for the 5th and 6th generation (5G/6G) wireless communication networks, along with increased signal bandwidth. To get high spectral efficiency and high-speed data transmission, highly modulated signals have been applied in the 5G/6G wireless communication networks, which have a large peak-to-average power ratio (PAPR). Meanwhile, the 3G, 4G, 5G and 6G communication standards are different, their modulation formats are different too. Different modulated signals have different PAPRs.

Therefore, a desired power amplifier should have a wide bandwidth, and a high power added efficiency (PAE) over a large power back-off range from the maximum output power. PAE is defined by an equation PAE=100×(Pout−Pin)/PDC, where PDC is input direct current (DC) power, Pout is RF output power and Pin is RF input power of the PA. It is desired that a PA operates close to the saturation point as that is where efficiency is maximum. The amount by which the power level is lowered is called power back-off. There are two power back-off types, input power back-off (IPBO) and output power back-off (OPBO). The IPBO is the power level at a PA input relative to the input power which produces the maximum output power. The OPBO is the power level at a PA output relative to the maximum output power level possible. For example, if the maximum output power level is +40 dBm, the measured output power level of the amplifier is +34 dBm, then the OPBO level is 6 dB.

For enhancing PA's efficiency at power back-off, a Doherty power amplifier (DPA) is the most widely applied topology. The DPA consists of a main amplifier and an auxiliary amplifier, as well as an impedance inverter, e.g. a quarter-wavelength transmission line. It has been investigated extensively how to extend DPA's bandwidth. Various techniques have been proposed.

In Yang Xu, et al., “Enhancing Bandwidth and Back-Off Range of Doherty Power Amplifier with Modified Load Modulation Network”, IEEE Transactions on Microwave Theory and Techniques, Vol. 69, No. 4, pp. 2291-2303, April 2021, a DPA was proposed where the impedance inverter consists of three quarter-wavelength transmission lines with respective character impedances.

In D. Gustafsson, et al., “A Novel Wideband and Reconfigurable High Average Efficiency Power Amplifier”, 2012 IEEE MTT-S Int. International Microwave Symposium Digest conference and proceedings, June 2012, and “Wideband and Reconfigurable Doherty Based Amplifier”, EP 2 705 601 B1, 2017, a modified DPA was proposed, where the characteristic impedance of the quarter-wavelength transmission line is equal to the load impedance and equal to impedance of the main amplifier in the low power region, i.e., when the auxiliary amplifier is switched off, therefore, the output impedance of the main amplifier is matched, and is frequency independent. By tuning the DC supply voltage of the main amplifier, the peak of the PAE at power back-off is reconfigurable from less than 6 dB up to 10 dB of OPBO.

In R. E. Mayer, et al., “High-efficiency amplifier”, U.S. Pat. No. 6,922,102 B2, it is proposed to use a quadrature coupler in a DPA to improve the DPA's efficiency at back-off power level.

In R. Giofrè et al., “New output combiner for Doherty amplifiers”, IEEE Microwave and Wireless Components Letters, Vol. 23, No. 1, pp. 31-33, January 2013, it is discussed how a quadrature coupler can be used to extend the bandwidth of the DPA. The quadrature coupler used here comprising 4 transmission lines, where the isolation port of the quadrature coupler is open.

In Y. Cao, et al., “Wideband Doherty Power Amplifier in Quasi-Balanced Configuration”, IEEE 20th Wireless and Microwave Technology Conference (WAMICON), 2019, another kind of quadrature coupler DPA is proposed where the isolation port of the quadrature coupler is grounded.

In Haifeng Lyu, et al., “Linearity-enhanced quasi-balanced Doherty power amplifier with mismatch resilience through series/parallel reconfiguration for massive MIMO”, IEEE Transactions on Microwave Theory and Techniques, Vol. 69, No 4, pp. 2319-2335 April 2021, a reconfigurable DPA with tuneable load at the isolation port (open or short) is proposed.

However, there are problems with the existing solutions. For examples, DPAs based on transmission lines (TLs) have a limited bandwidth, even though multi-TLs inverter increases the bandwidth with a certain extension.

The modified DPA proposed by D. Gustafsson et. al., requires a reduced voltage supply of the main amplifier. The reduced voltage supply of the main amplifier results in a reduced maximum power of the main amplifier P_{max,main}, which in turn gives low power utilization factor, defined as P_{max,DPA}/(P_{max,main}+P_{max,aux.}), where P_{max,DPA} is the power of the DPA, P_{max,aux.} is the power of the auxiliary amplifier.

Even though DPAs based on quadrature coupler have better bandwidth performance than TLs based ones, the peak drain efficiency (PDE) is at 6 dB of OPBO. Drain efficiency (DE) is the ratio of output RF power (Pout) to the input DC power (PDC) defined as DE=Pout/PDC. It is not shown if DPAs based on quadrature couplers are applicable for PDE at deep OPBO, i.e. larger than 6 dB of OPBO.

DPA based on coupled lines with grounded isolation port requires a large coupling coefficient, k, to enhance the bandwidth. Unfortunately, it is difficult to realize a large k, e.g. larger than 0.8 in in Gallium nitride (GaN) or Gallium arsenide (GaAs) semiconductor process where only side-by-side coupled lines with moderate k are available.

### SUMMARY

Therefore, it is an object of embodiments herein to provide a power amplifier arrangement with improved bandwidth and efficiency at an arbitrary power back-off level.

Up to now, the PAE of the DPAs based on quadrature couplers is frequency dependent in low power region, because quadrature coupler based on coupled lines is not used, and the load resistor is not equal to the optimum back-off impedance of the main amplifier at low power region.

According to one aspect of embodiments herein, the object is achieved by a power amplifier arrangement which is a Doherty power amplifier based on two coupled transmission lines. The power amplifier arrangement comprises a first power amplifier having an input and an output, which is a main amplifier, and a second a power amplifier having an input and an output, which is an auxiliary amplifier.

The power amplifier arrangement further comprises an input power splitter having an input and a first output and a second output.

The power amplifier arrangement further comprises a quadrature coupler having an input port, a through port, a coupled port and an isolated port. The quadrature coupler comprises two coupled transmission lines, a first terminal of the first transmission line is the input port, a second terminal of the first transmission line is the through port, a first terminal of the second transmission line is the coupled port and a second terminal of the second transmission line is the isolated port.

The input of the first power amplifier is coupled to the first output of the input power splitter; the output of the first power amplifier is coupled to the through port of the quadrature coupler; the input of the second power amplifier is coupled to the second output of the input power splitter; the output of the second power amplifier is coupled to the coupled port of the quadrature coupler; the input port of the quadrature coupler is coupled to a load; and the isolated port of the quadrature coupler is not connected to any component.

A coupling coefficient of the two coupled transmission lines is determined based on an output power backoff level at which the power amplifier arrangement is desired to operate.

According to some embodiments herein, the coupling coefficient of the two coupled transmission lines may be determined to be equal to a transition point of a voltage drive level for the power amplifier arrangement. The transition point of the voltage drive level is a normalized voltage drive level where the second power amplifier is at an onset or about to turn on, and the transition point of the voltage drive level is related to the output power back-off level.

In other words, the power amplifier arrangement according to embodiments herein is a Doherty PA based on two coupled transmission lines which forms a quadrature coupler. The main amplifier and load impedance are connected to the two terminals of the first transmission line respectively. The auxiliary amplifier is connected to one terminal of the second transmission line and the other terminal is open. The load impedance is equal to the wanted or optimum load impedance presented to the main amplifier at low power region, i.e., when the auxiliary amplifier is off. Selecting the coupling coefficient of the two coupled transmission lines based on an output power backoff level at which the power amplifier is desired to operate, the PAE at low power region is insensitive to frequency, thus, the bandwidth of the power amplifier arrangement according to embodiments herein is enhanced.

The power amplifier arrangement according to embodiments herein has some advantages:
Having wider bandwidth than a conventional DPA;
Can have DE peak at an arbitrary output power back-off level;
A coupled TLs with a moderate coupling coefficient, e.g. k≈0.5, is appliable, such kind of coupled lines can be implemented easily in Gallium nitride (GaN) or Gallium arsenide (GaAs) semiconductor technology where only side-by-side coupled lines can be built.

Improved power utilization factor since the drain supplier voltage of the main amplifier is equal to that of the auxiliary amplifier.

Therefore, embodiments herein provide a power amplifier arrangement with improved bandwidth and efficiency at an arbitrary power back-off level.

### BRIEF DESCRIPTION OF THE DRAWINGS

Examples of embodiments herein are described in more detail with reference to attached drawings in which:

FIG. 1 is a schematic block diagram illustrating a power amplifier arrangement according to embodiments herein;

FIG. 2 is a simplified schematic block diagram illustrating the power amplifier arrangement according to embodiments herein;

FIG. 3 is a diagram showing simulation results on drain efficiency versus output power at different normalized frequencies for the power amplifier arrangement according to embodiments herein;

FIG. 4 is a diagram showing simulation results on drain efficiency versus output power at different normalized frequencies for the power amplifier arrangement according to embodiments herein;

FIG. 5 is a diagram showing simulation results on drain efficiency versus output power for a conventional DPA; and

FIG. 6 is a block diagram illustrating an electronic device/apparatus in which embodiments herein may be implemented.

### DETAILED DESCRIPTION

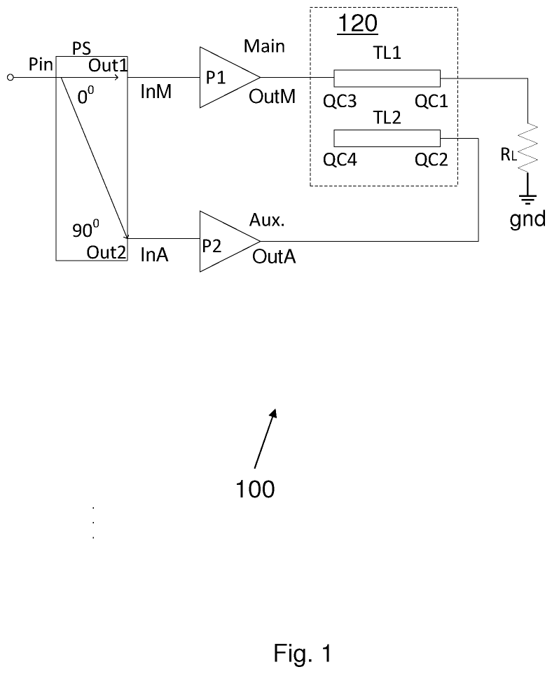

FIG. 1 shows a schematic block diagram of a power amplifier arrangement 100 according to embodiments herein, which is a Doherty power amplifier based on two coupled transmission lines. The power amplifier arrangement 100 comprises a first power amplifier P1 having an input InM and an output OutM, which is a main amplifier Main in the Doherty power amplifier arrangement 100, and a second power amplifier P2 having an input InA and an output OutA, which is an auxiliary amplifier Aux. in the Doherty power amplifier arrangement 100.

The power amplifier arrangement 100 further comprises an input power splitter PS having an input port Pin and two output ports, a first output Out1 and a second output Out2.

The power amplifier arrangement 100 further comprises a quadrature coupler 120 having an input port QC1, a through port QC3, a coupled port QC2 and an isolated port QC4. The quadrature coupler 120 comprises two coupled transmission lines TL1, TL2. A first terminal of the first transmission line TL1 is the input port QC1 and a second terminal of the first transmission line TL1 is the through port QC3. A first terminal of the second transmission line TL2 is the coupled port QC2 and a second terminal of the second transmission line TL2 is the isolated port QC4.

The input InM of the first power amplifier P1 is coupled to the first output Out1 of the input power splitter PS.

The output OutM of the first power amplifier P1 is coupled to the through port QC3 of the quadrature coupler 120.

The input InA of the second power amplifier P2 is coupled to the second output Out2 of the input power splitter PS.

The output OutA of the second power amplifier P2 is coupled to the coupled port QC2 of the quadrature coupler 120.

The input port QC1 of the quadrature coupler 120 is coupled to a load R_{L} which is coupled to an Alternating Current (AC) ground gnd.

The isolated port QC4 of the quadrature coupler 120 is open, i.e. not connected to any component.

According to embodiments herein, a coupling coefficient of the two coupled transmission lines TL1/TL2 is determined based on an output power backoff level at which the power amplifier arrangement 100 is desired to operate.

The load R_{L} may be equal to the optimal load impedance of the main amplifier P1 at low power region, i.e., when the auxiliary amplifier P2 is off. If the characteristic impedance of the coupling lines TL1 and TL2 and the coupling coefficient are selected according to design equations derived in the following, the DE at low power region will be insensitive to frequency, therefore, the bandwidth of the power amplifier arrangement 100 will be enhanced.

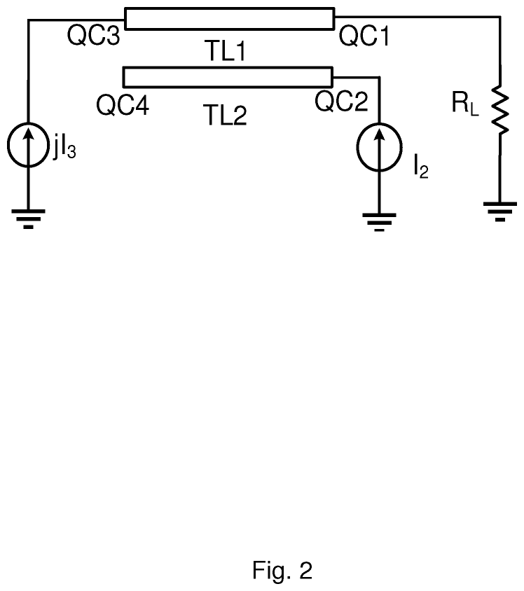

In the flowing, the design equations will be derived and how to design the power amplifier arrangement 100 for peak drain efficiency at any arbitrary OPBO level will be described with reference to FIG. 2.

FIG. 2 shows a simplified schematic of the power amplifier arrangement 100, wherein the quadrature coupler 120 comprising two coupled transmission lines TL1 and TL2 is shown, and the main and auxiliary amplifiers P1, P2 are represented by a voltage controlled current source, jI₃ and I₂, respectively, where j=\sqrt{−1} represents 90° phase difference between I₂ and I₃ The isolation port, i.e., the 4-th port QC4 is open and the input port, i.e., the first port QC1 is terminated by the load impedance/resistor R_{L}. In a first approximation, the transistors' parasitic is neglected.

The length of the two coupled transmission lines TL1, TL2 may be a quarter-wavelength at a centre frequency of an RF input signal to the power amplifier arrangement 100.

For transverse electromagnetic wave (TEM) and symmetric transmission lines, impedance matrix for the 4-port coupled transmission lines is given by

$$[ \begin{matrix}{V}_{1} \\ {V}_{2} \\ {V}_{3} \\ {V}_{4}\end{matrix} ] = \frac{- j}{2} [ \begin{matrix}0 & 0 & {Z}_{+} & {Z}_{-} \\ 0 & 0 & {Z}_{-} & {Z}_{+} \\ {Z}_{+} & {Z}_{-} & 0 & 0 \\ {Z}_{-} & {Z}_{+} & 0 & 0\end{matrix} ] [ \begin{matrix}{I}_{1} \\ {I}_{2} \\ {I}_{3} \\ {I}_{4}\end{matrix} ] \qquad ( 1 )$$

Where, V₁, V₂, V₃, V₄ are voltages at the 4 ports respectively, and I₁, I₂, I₃, I₄ are currents of the 4 ports respectively Z₋=Z₀ₑ−Z₀ₒ and Z₊=Z₀ₑ+Z₀ₒ. Here Z₀ₑ and Z₀ₒ are the even-mode and odd-mode impedances of the coupled transmission lines, respectively. Z₀ₑ and Z₀ₒ are related to Z₀=\sqrt{ZₒₑZₒₒ}, and coupling coefficient

$$k = \frac{{Z}_{-}}{{Z}_{+}} ( 0 < k < 1 ) :$$

$${Z}_{oe} = {Z}_{0} \sqrt{\frac{1 + k}{1 - k}} \qquad ( 2 a )$$

$${Z}_{oo} = {Z}_{0} \sqrt{\frac{1 - k}{1 + k}} \qquad ( 2 b )$$

Even and odd modes are the two main modes of propagation of a signal through a pair of coupled transmission lines. Odd mode impedance Z₀ₒ is defined as impedance of a single transmission line when the two coupled transmission lines are driven differentially with signals of the same amplitude and opposite polarity. Even mode impedance Z₀ₑ is defined as impedance of a single transmission line when the two coupled transmission lines are driven with a common mode signal of the same amplitude and the same polarity.

The 4^{th} port QC4 is open, thus, I₄=0. The first port QC1 is terminated by the resistor R_{L}, so V₁=−R_{L}I₁. Inserting those two equations into equation (1), obtaining

$$[ \begin{matrix}{V}_{2} \\ {V}_{3}\end{matrix} ] = \frac{- j}{2} [ \begin{matrix}0 & {Z}_{-} \\ {Z}_{-} & \frac{j}{2} \frac{{Z}_{+}^{2}}{{R}_{L}}\end{matrix} ] [ \begin{matrix}{I}_{2} \\ {I}_{3}\end{matrix} ] \qquad ( 3 )$$

When the auxiliary amplifier is off, I₂=0, the impedance at the third port QC3 is thus given by

$${Z}_{3} = \frac{{Z}_{+}^{2}}{4 {R}_{L}} \qquad ( 4 )$$

When the auxiliary amplifier is off, the impedance of the main amplifier Z₃ is equal to

$$\frac{{R}_{opt}}{{ξ}_{b}} ,$$

where Rₒₚₜ is the optimal load impedance of the main amplifier at full power, i.e., the desired load impedance of the first power amplifier P1 at full power. At the optimal load impedance Rₒₚₜ, the first power amplifier P1 delivers a maximum output power. ξ is the normalized voltage drive level, where 0<ξ<1, and ξ_{b} is a transition point of the normalized voltage drive level where the auxiliary amplifier is at an onset or about to turn on. ξ_{b} is related to an output power back-off (OPBO) level P_{BO} by equation

$${P}_{BO} = - 20 log ( {ξ}_{b} )$$

Therefore, one can get

$${R}_{L} = \frac{{ξ}_{b} {Z}_{+}^{2}}{4 {R}_{opt}} \qquad ( 5 )$$

Furthermore, at peak output power, ξ=1, the impedance of the main amplifier decreases to:

$${Z}_{3} = {R}_{opt} \qquad ( 6 a )$$

The maximum current of the auxiliary amplifier is related to the maximum current of the main amplifier and is given by

$${I}_{2} = - \frac{1 - {ξ}_{b}}{{ξ}_{b}} \cdot {jI}_{3} \qquad ( 6 b )$$

In equation (6b), −j represents the phase shift between I₃ and I₂.

Inserting equations (6a) and (6b) into equation (3), and utilizing equation (5), one gets

$${R}_{opt} = \frac{{Z}_{-}}{2} \qquad ( 7 )$$

Inserting equation (2) into equations (5) and (7) one gets

$${R}_{L} = \frac{{ξ}_{b}}{{k}^{2}} {R}_{opt} \qquad ( 8 )$$

$${Z}_{0} = \frac{\sqrt{1 - {k}^{2}}}{k} {R}_{opt} \qquad ( 9 )$$

The optimal load impedance Rₒₚₜ of the main amplifier is determined by the maximum current of the main amplifier I_{m,max}, and a supply voltage to the main amplifier, ξ_{b} is determined by the OPBO level giving peak drain efficiency. The characteristic impedance Z₀ of the coupled transmission lines is determined by the coupled transmission line's width and separation for a given substrate of a semiconductor technology. The coupling coefficient k of the two coupled transmission lines TL1/TL2 is mainly determined by their separation distance for a given substrate of a semiconductor technology.

The coupling coefficient k, where k<1, is a “free” parameter. k may be determined to be equal to ξ_{b}:

$$k = {ξ}_{b} \qquad ( 10 )$$

In this case, according to equation (8), R_{L} will be equal to

$$\frac{{R}_{opt}}{{ξ}_{b}}$$

which is the impedance of the main amplifier when the auxiliary amplifier is off. At peak output power, the impedance of the auxiliary amplifier is

$${Z}_{2} = \frac{{V}_{2}}{{I}_{2}} = {R}_{opt} \frac{{ξ}_{b}}{1 - {ξ}_{b}} \qquad ( 11 )$$

which is obtained by utilizing equations (3), (6b) and (7).

The equations derived above describe how to build a wide bandwidth PA for peak efficiency at any arbitrary OPBO levels, i.e. for any transition point ξ_{b} of the voltage drive level.

For an arbitrary transition point ξ_{b} of the voltage drive level related to an output power backoff level at which the power amplifier arrangement is desired to operate, a coupling coefficient k of the two coupled transmission lines TL1/TL2 may be based on the transition point ξ_{b} of the voltage drive level. For example, one can choose k=ξ_{b}, i.e. the coupling coefficient of the two coupled transmission lines TL1/TL2 may be determined to be equal to the voltage drive level ξ_{b} for the power amplifier arrangement 100. The coupling coefficient of the two coupled transmission lines TL1/TL2 is determined mainly by their separation distance for a given substrate of a semiconductor technology. So, during design stage, one can configure the separation distance of the two transmission lines TL1/TL2 for a given substrate to get different coupling coefficients for matching different ξ_{b}.

Then, an optimal load impedance Rₒₚₜ of the main power amplifier may be determined. At the optimal load impedance Rₒₚₜ, the main power amplifier delivers a maximum output power. The optimal load impedance Rₒₚₜ of the main amplifier is determined by the maximum current of the main amplifier I_{m,max} and the supply voltage of the main amplifier.

The characteristic impedance Z₀ of the two coupled transmission lines TL1/TL2 is determined based on the optimal load impedance of the first power amplifier P1 and the coupling coefficient of the two coupled transmission lines TL1/TL2, by the equation (9):

$${Z}_{0} = \frac{\sqrt{1 - {k}^{2}}}{k} {R}_{opt}$$

When the maximum current of the main amplifier I_{m,max} and the OPBO level, i.e., ξ_{b} are determined, the magnitude of the maximum current of the auxiliary amplifier I_{a,max} is determined by the equation (6b):

$${I}_{a , max} = \frac{1 - {ξ}_{b}}{{ξ}_{b}} \cdot {I}_{m , max}$$

Assuming the maximum current is proportional to the devices size, the ratio of the size of the auxiliary and the main amplifier devices in the power amplifier arrangement 100 can be determined too.

The load of the quadrature coupler is determined based on the optimal load impedance Rₒₚₜ of the first power amplifier P1 and the transition point of the voltage drive level ξ_{b} at which the second amplifier P2 is at an onset or about to turn on, by equation:

$${R}_{L} = \frac{{R}_{opt}}{{ξ}_{b}}$$

To demonstrate the proposed power amplifier arrangement 100 can have DE peak at different transition points of the voltage drive level ξ_{b} corresponding different OPBO levels, the power amplifier arrangement 100 with the same main amplifier size and current, all having Rₒₚₜ and I_{m,max} equal to 50Ω and 1 A, respectively, operating at different transition points of the voltage drive levels and different frequencies, are simulated.

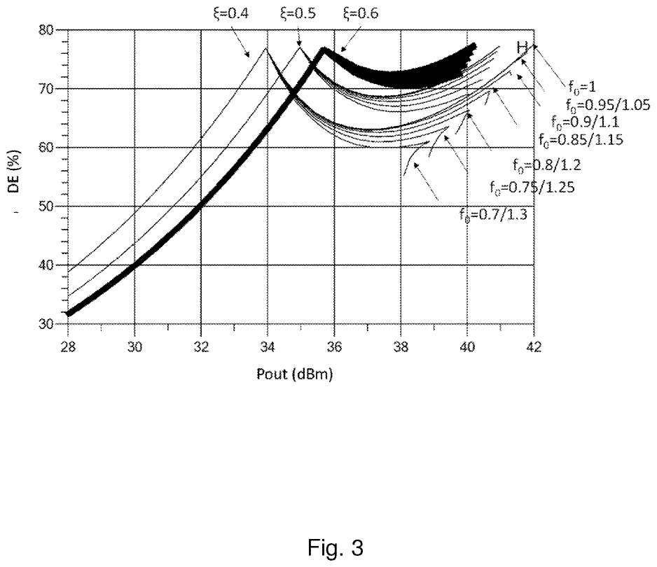

To make the DE independent of the frequency, when the auxiliary amplifier is switched off, k is chosen to be equal to b. The drain efficiency (DE) versus output power at different frequencies for different transition points, which is equal to 0.4, 0.5, and 0.6 respectively are plotted in FIG. 3, where the frequencies labelled in figure is a normalized frequency f₀=f/f_{c}, here f_{c} is the center frequency. As can be seen, the power amplifier arrangement 100 has two DE peaks, one peak at the maximum output power, and another one at an output power back-off level corresponding to the transition point.

It can be seen, when the output power is less than OPBO level, i.e. the output power is below the transition point, the DE is independent of frequency. For example, for ξ_{b}=0.6, where Pout<36 dBm, for ξ_{b}=0.5, where Pout<35 dBm, for ξ_{b}=0.4, where Pout<34 dBm, the DE curves for different frequencies are almost overlap with each other.

The deeper the peak of DE at back-off power level is, i.e. the lower or smaller the ξ_{b}, the larger is the maximum current of the auxiliary amplifier (see equation (6b)), thus, the larger is the maximum output power of the power amplifier arrangement 100. For a given ξ_{b}, the maximum output power decreases, as the frequency apart from the center frequency. It is not obviously when ξ_{b} is equal to 0.5 and 0.6. But when ξ_{b}=0.4, the maximum output power drops with increasing frequency range, e.g. when the normalized frequency f₀=0.7 or 1.3, the maximum output power is 39 dBm, the maximum output power is 42 dBm when the frequency is at the center frequency, i.e. f₀=1.

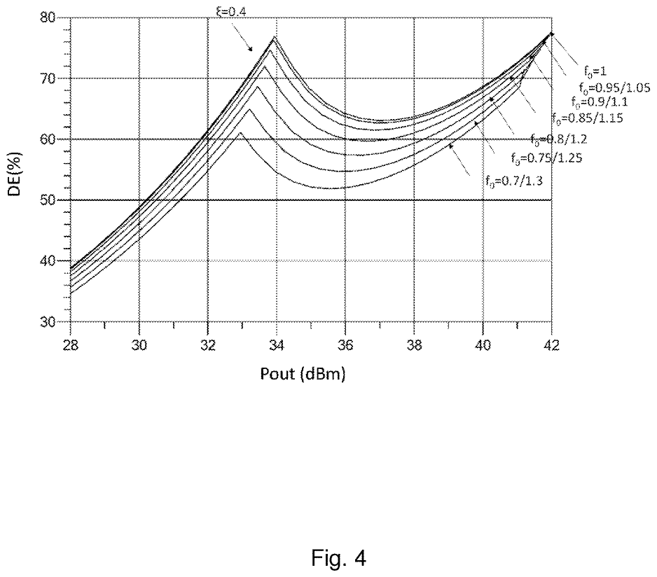

When ξ_{b}=0.4, a trade-off between high DE and high output power can be made. FIG. 4 shows DE versus output power at different frequencies, when k=0.6, ξ_{b}=0.4. As can be seen, when increasing k from 0.4 to 0.6, the maximum output power decreases about 1 dB from 42 dBm to 41 dBm, while the DE peak is degraded from 76% to 61%, at the normalized frequency equal to 1.3 or 0.7, comparing to k=0.4.

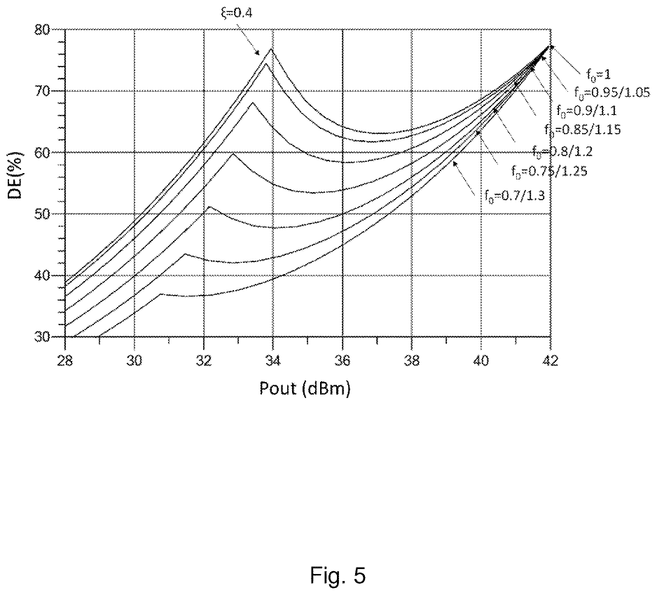

Nevertheless, the DE of the proposed power amplifier arrangement 100 is better than a conventional DPA where a quarter-wavelength TL replacing the quadrature coupler. The DE versus output power of a conventional DPA when ξ_{b}=0.4, is plotted in FIG. 5. As can be seen, the peak DE drops to 37% at the normalized frequency equal to 1.3 or 0.7 compared to 61% of the proposed power amplifier arrangement 100.

Therefore, it has been demonstrated that the power amplifier arrangement 100 according to embodiments herein has some advantages:
Having wider bandwidth than a conventional DPA;
Can have DE peak at an arbitrary output power back-off level;
A coupled TLs with a moderate coupling coefficient, e.g. k≈0.5, is appliable, such kind of coupled lines can be implemented easily in Gallium nitride (GaN) or Gallium arsenide (GaAs) semiconductor technology where only side-by-side coupled lines can be built.

Improved power utilization factor since the drain supplier voltage of the main amplifier is equal to that of the auxiliary amplifier.

To summarize, the power amplifier arrangement 100 according to embodiments herein is a quadrature coupler based DPA, which can be designed to have efficiency peak at an arbitrary OPBO level. The quadrature coupler 120 may be realized by two coupled transmission lines TL1/TL2 with a length of a quarter wavelength at a centre frequency of an RF signal. The isolation port of the quadrature coupler is open. The coupling coefficient k of the two coupled transmission lines TL1/TL2 is determined based on an output power backoff level at which the power amplifier arrangement 100 is desired to operate. The coupling coefficient k may be equal to the transition point ξ_{b} of the voltage drive level of the power amplifier arrangement 100. The characteristic impedance Z, of the coupled transmission lines TL1/TL2 is determined by the optimal impedance of the main amplifier and the coupling coefficient k of the two coupled transmission lines TL1/TL2. The load impedance R_{L} at the first port QC1 of the quadrature coupler 120 is determined by the optimal impedance of the main amplifier and transition point ξ_{b} of the voltage drive level.

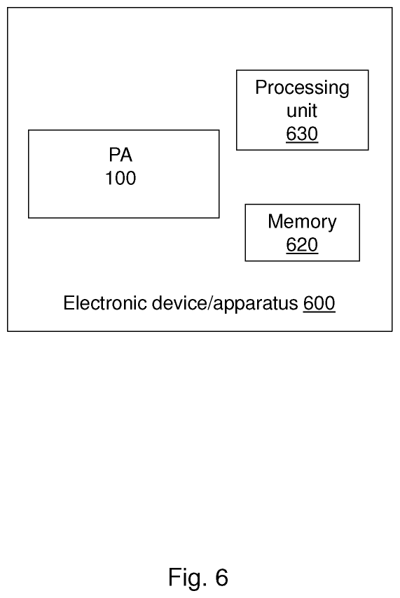

The power amplifier arrangement 100 according to embodiments herein may be employed in various electronic devices or apparatus etc. FIG. 6 shows a block diagram for an electronic device or apparatus 600. The electronic device or apparatus 600 comprises a power amplifier arrangement 100 according to embodiments herein. The electronic device 600 may be a transmitter, a transceiver, a base station, a mobile device, a user equipment, a wireless communication device, a radar for a communication system. The electronic device 600 may comprise other units, where a memory 620, a processing unit 630 are shown.

The embodiments herein are not limited to the above described preferred embodiments. Various alternatives, modifications and equivalents may be used. Those skilled in the art will understand that the power amplifier arrangement 100 according to embodiments herein may be implemented in Printed Circuit Board with discreate transistors or any semiconductor technology, e.g. Bi-polar, N-type Metal Oxide Semiconductor (NMOS), P-type Metal Oxide Semiconductor (PMOS), Complementary Metal Oxide Semiconductor (CMOS), Silicon on Insulator (SOI) CMOS, field-effect transistor (FET), MOSFET technology etc.

When using the word “comprise” or “comprising” it shall be interpreted as non-limiting, i.e. meaning “consist at least of”. Therefore, the above embodiments should not be taken as limiting the scope of the invention, which is defined by the appended claims.

1. A power amplifier arrangement, wherein the power amplifier arrangement is a Doherty power amplifier based on two coupled transmission lines, the power amplifier arrangement comprising:
a first power amplifier having an input and an output, which is a main amplifier, and a second a power amplifier having an input and an output, which is an auxiliary amplifier;
an input power splitter having an input and a first output and a second output; and
a quadrature coupler having an input port, a through port, a coupled port and an isolated port, wherein the quadrature coupler comprises two coupled transmission lines, a first terminal of the first transmission line is the input port, a second terminal of the first transmission line is the through port, a first terminal of the second transmission line is the coupled port and a second terminal of the second transmission line is the isolated port;
wherein:
the input of the first power amplifier is coupled to the first output of the input power splitter;
the output of the first power amplifier is coupled to the through port of the quadrature coupler;
the input of the second power amplifier is coupled to the second output of the input power splitter;
the output of the second power amplifier is coupled to the coupled port of the quadrature coupler;
the input port of the quadrature coupler is coupled to a load; and
the isolated port of the quadrature coupler is not connected to any component; and
a coupling coefficient of the two coupled transmission lines is determined based on an output power backoff level at which the power amplifier arrangement is desired to operate.

2. The power amplifier arrangement of claim 1, wherein the coupling coefficient of the two coupled transmission lines is determined to be equal to a transition point (ξ_{b}) of a voltage drive level for the power amplifier arrangement, and wherein the transition point (ξ_{b}) of a voltage drive level is a voltage drive level at which the second amplifier is at an onset, and is related to the output power backoff level.

3. The power amplifier arrangement of claim 1, wherein the coupling coefficient of the two coupled transmission lines is determined by their separation distance for a given substrate.

4. The power amplifier arrangement of claim 1, wherein a characteristic impedance of the two coupled transmission lines is determined based on an optimal load impedance of the first power amplifier and the coupling coefficient of the two coupled transmission lines, wherein at the optimal load impedance, the first power amplifier delivers a maximum output power.

5. The power amplifier arrangement of claim 4, wherein the characteristic impedance of the two coupled transmission lines is determined by an equation
$${Z}_{0} = \frac{\sqrt{1 - {k}^{2}}}{k} \cdot {R}_{opt} ,$$
where Z₀ is the characteristic impedance of the coupled transmission lines, Rₒₚₜ is the optimal load impedance of the first power amplifier, and k is the coupling coefficient of the two coupled transmission lines.

6. The power amplifier arrangement of claim 1, wherein the load impedance of the quadrature coupler is determined based on an optimal load impedance of the first power amplifier and the output power backoff level.

7. The power amplifier arrangement of claim 6, wherein the load impedance of the quadrature coupler is determined by an equation
$${R}_{L} = \frac{{R}_{opt}}{{ξ}_{b}} ,$$
wherein R_{L} is the load impedance, Rₒₚₜ is the optimal load impedance of the first power amplifier, ξ_{b} represents a voltage drive level at which the second amplifier is at an onset, which is related to the output power backoff level by an equation P_{BO}=−20 log(ξ_{b}), wherein P_{BO} is the output power backoff level.

8. An electronic device comprising a power amplifier arrangement of claim 1.

9. The electronic device according to claim 8, wherein the electronic device is any one of a transmitter, a transceiver, a base station, a mobile device, a user equipment, and a wireless communication device for a communication system.
